(19) United States
(12) Patent Application Publication
(10) Pub. No.: US 2026/0088106 A1
(43) Pub. Date: Mar. 26, 2026

(54) DIFFERENTIAL MEMORY

(71) Applicant: Shanghai Huali Integrated Circuit Corporation, Shanghai (CN)

(72) Inventors: Jielin SHI, Shanghai (CN); Hao LIU, Shanghai (CN)

(73) Assignee: Shanghai Huali Integrated Circuit Corporation, Shanghai (CN)

(21) Appl. No.: 19/220,964

(22) Filed: May 28, 2025

(30) Foreign Application Priority Data
Sep. 25, 2024 (CN) 202411347961.X

(51) Int. Cl. G11C 16/28; G11C 16/08

(52) U.S. Cl. CPC G11C 16/28; G11C 16/08

(57) ABSTRACT

The present application discloses a differential memory, bit lines of M+1 storage cells of a (x)th array cell and bit lines of M+1 storage cells of a (x−1)th array cell are arranged sequentially in a staggered and spaced pattern in a physical arrangement, and thus, bit lines of a group of storage cell arrays storing M bits of data with M+1 storage cells are separated by bit lines of another group of storage cell arrays, and a misreading risk resulted from crosstalk caused by simultaneous discharging of two adjacent bit lines during reading can be avoided while retaining a current-comparison reading mode for a differential storage cell without increasing a storage array area, further enlarging a read window to realize more stable data reading based on a more stable differential reading principle relative to a traditional reference current type.

### CROSS-REFERENCE TO RELATED APPLICATIONS

This application claims priority to Chinese patent application No. 202411347961.X, filed on Sep. 25, 2024, the disclosure of which is incorporated herein by reference in its entirety.

### TECHNICAL FIELD

The present application relates to semiconductor memory technology, and particularly to a differential memory.

### BACKGROUND

In the prior art, a reading mode for and address arrangement of a reference-current-type storage array are shown in FIG. 1, and by utilizing the feature that a storage cell storing “1” and a storage cell storing “0” having different threshold voltages vt have different saturation currents at an identical gate voltage, with a fixed current between the different saturation currents as a reference, stored data is read by comparing a current of a storage cell (bit cell) with a size of a reference current. The storage cell has an address arrangement pattern that word lines and bit lines in the cell are sequentially arranged in an address ascending order with one array cell corresponding to a single-bit output; under multi-bit output, a plurality of array cells expand horizontally to form a block to realize simultaneous multi-bit writing and reading, and when a selected block is read, neighboring blocks are as a reference, and respective bit lines are subjected to discharging at a reference current; and under a high capacity, a plurality of blocks form a full array of storage cells. When a read action is triggered by a clock signal, address mapping makes a respective bit line of a selected block and a bit line, in a reference block, having an identical address are pre-charged to an identical potential, then the two bit lines are discharged through storage cells (bit cell) at corresponding addresses, respectively, and at a reference current, the potentials of the two bit lines are inputted into sensitive amplifiers for comparison, and the data of the storage cell (bit cell) is read; and a plurality of sensitive amplifiers output multi-bit results in parallel.

Such an address-ascending arrangement pattern has the advantage. Only selected address bit lines of each array cell are subjected to charging and discharging operations, surrounding non-selected address bit lines have no current therethrough in a read cycle, there is no interference between bit lines of selected addresses, and between different output bits, individual array cells and respective sensitive amplifiers work separately to output results, and the array cell has a high utilization rate. It has disadvantage. A selected block is far away from a reference block, the two bit lines for reading and reference having an identical address have parasitized random deviations due to a manufacturing process, and that affects the accurate reflection of the storage cell current through the voltage window, thereby increasing a misreading risk with a poor reliability.

To increase a reliability of a memory, a reading method and an address arrangement pattern for an existing differential contrast storage array are as shown in FIG. 2, a read window is enlarged by comparing current windows of a storage cell (bit cell) storing “0” and a storage cell storing “1”, and a global reference current avoids to be used by utilizing the feature that a local mismatch is smaller than a global mismatch, realizing more stable data reading. In this reading method for a differential contrast storage array, a reference storage cell (reference bit cell) is placed near each optional storage cell (bit cell) and store inverted data relative to the data in each optional storage cell. Two bit lines where the reference storage cell and each optional storage cell are located are both selected when reading, and stored data is read by discharging through a respective storage cell (bit cell) to compare the discharge speeds of the selected optional storage cell and its reference storage cell (reference bit cell). An address arrangement pattern of storage cells is that two adjacent storage cells on every two bit lines referred as a group of differential array cells (cell), one (an optional storage cell) storing a bit of data and the other one (a reference storage cell) constantly storing inverted data relative to the data, are selected by an identical address for programming and reading; in an array cell corresponding to one-bit output, a differential array cell (cell) is arranged in an address ascending order, and a pair of differential bit lines is selected under address mapping to read a bit of data; in a multi-bit-output memory, a plurality of array cells expand laterally to form a block; and one or more blocks are divided according to a capacity size to form a full array.

To improve an utilization rate of an array cell (cell) and reduce an IP (intellectual property core) area, the improved reading solution for a differential contrast storage array shown in FIG. 3a and FIG. 3b improves the storage and reading technical solution for a differential array cell (cell) shown in FIG. 2, in the improved reading solution, every M+1 storage cells (bit cell) store M bits of data, that is, in neighboring M+1 bit lines, two storage cells (bit cell) store 1 bit of data for a group of differential array cells (cell), and bit line potentials of the two storage cells are inputted to a sensitive amplifier to compare storage cell (bit cell) currents to read data, referring to FIG. 3a; and remaining M−1 storage cells (bit cell) store M−1 bits of data for a non-differential array cell, the average discharging rate of the differential array cells (cell) is compared with that of the non-differential array cells (cell) by M−1 sensitive amplifiers having special structures to determine stored data, and ultimately, M bits are output, referring to FIG. 3b.

The improved reading solution for a differential contrast storage array shown in FIG. 3a, and FIG. 3b has a storage cell address arrangement pattern similar to that of the differential array cell (cell) shown in FIG. 2, neighboring M+1 bit lines, as a group, are selected by an identical address for programming and reading; one array cell outputs M bits, each group of storage cells (bit cell) are arranged in an address ascending order, a group of bit lines are selected under address mapping to read M-bit data; under N pieces of Mbit output, N array cells expand horizontally to form a block of N*M-bit output; and single or multiple blocks form a full array.

Under the address-ascending arrangement pattern shown in FIG. 3a, and FIG. 3b, different array cells do not interfere with each other and work separately to output results, and also a group of storage cells (bit cell) selected for comparing and reading within each array cell are in adjacent positions, currents of neighboring “0” storage cell and “1” storage cell are both small or large during distribution, a relatively large read window (margin) can be ensured, and in addition, adjacent bit lines have a relatively small parasitic deviation, effectively reducing the misreading risk resulted from the parasitic deviation.

The reading method and address arrangement pattern for a differential contrast storage array as shown in FIG. 2 have a disadvantage that an adverse factor of crosstalk exits. Taking a differential array cell (cell) as an example, bit lines where differential array cells (cell) are located are discharged simultaneously during a read cycle, and since two bit lines are adjacent and too close, there is a relatively large parasitic capacitance between the bit lines. Referring to FIG. 4a, bit line addresses at both sides of the differential array cell (cell) are grounded because they are not selected, a size C of a parasitic capacitance exists between adjacent bit lines, and assuming a read bit line being first pre-charged to Vᵢₙᵢ during a read cycle, a “0” storage cell being read on bl<n>, a discharge current i_cell0=i, a “1” storage cell being read on blb<n>, a discharge current i_cell1 being approximated 0, potentials of two bit lines being reduced to V₀ and V₁ after time t, respectively, and a read window ΔV=V_1-V_0, there are:

$${CV}_{ini} - it = C ( {V}_{0} - {V}_{1} ) + {CV}_{0} , \qquad ( Equation 3.1 )$$

$$and$$

$${CV}_{ini} - 0 = C ( {V}_{1} - {V}_{0} ) + {CV}_{1} \qquad ( Equation 3.2 )$$

A read window is obtained via calculation according to equations 3.1 and 3.2 as

$$Δ V = {V}_{1} - {V}_{0} = \frac{it}{3 C} ,$$

where i is a discharge current.

Referring to FIG. 4b, if a shielded line is added in the middle of a differential address to avoid crosstalk, assuming a size C of a parasitic capacitance also existing between lines, a read bit line being precharged to Vᵢₙᵢ, and potentials of two bit lines being reduced to V₀′ and V₁′, respectively, after discharge time t, there are:

$$2 {CV}_{ini} = it + 2 {CV}_{0}^{′} , \qquad ( Equation 3.3 )$$

$$and$$

$$2 {CV}_{ini} = 0 + 2 {CV}_{1}^{′} \qquad ( Equation 3.3 )$$

A read window is obtained via calculation according to equations 3.3 and 3.4 as

$$Δ {V}^{′} = {V}_{1}^{′} - {V}_{0}^{′} = \frac{it}{2 C} .$$

Thus, crosstalk between differential address bit lines causes a read window to significantly reduce relative to the case where the middle is subjected to isolation with a shielded line. If a shielded line can be added between bit lines selected for reading, an estimated read window can be expanded from

$$\frac{it}{3 C} to \frac{it}{2 C}$$

at maximum, an increase in 50%.

Similarly, the improved reading solution for a differential contrast storage array shown in FIG. 3a, and FIG. 3b also has such a problem, each group of M+1 adjacent bit lines are selected simultaneously and subjected to discharging at different current magnitudes of respective storage cells (bit cell), leading to signal crosstalk. If opposite numbers are exactly adjacent, bit line potentials suppress each other under different discharge rates of a “1” storage cell and a “0” storage cell, resulting in a reduced read window finally input to a sensitive amplifier, so as to increase a misreading risk. Therefore, such an address arrangement pattern has the problem of crosstalk, which in turn limits the increase of the memory read window and needs to be solved.

FIG. 5a shows a differential contrast storage array with 4 sonos storage cells storing 3-bit and without shielded line isolation in the middle, sonos storage cells on bit lines bl0<0>, bl0b<0>, bl1<0>, and bl2<0> store 0, 1, 0, and 1, respectively, and due to a small spacing of neighboring bit lines and a long track, the parasitic capacitance between bit lines is relatively large, and crosstalk occurs for bit line signals when a shielded line is not in the middle. In the read cycle, a bit line is subjected to discharging by a storage cell, the voltages of the bit lines where the “1” storage cell and the “0” storage cell are located change with time, the “0” storage cell discharges faster than the “1” storage cell, the bit line potentials of the “0” storage cell and the “1” storage cell suppress each other under the influence of crosstalk, and the difference of the voltages inputted by the “1” storage cell and the “0” storage cell to the sensitive amplifier decreases, referring to FIG. 6, resulting in a reduced read window.

FIG. 5b shows a differential contrast storage array with 4 sonos storage cells storing 3-bit and with shielded line isolation in the middle, and a circuit with spaced-address arrangement avoids the effect of crosstalk under a read action.

### BRIEF SUMMARY

The technical problem to be solved by the present application is to provide a differential memory, and a misreading risk resulted from crosstalk caused by simultaneous discharging of two adjacent bit lines during reading can be avoided while retaining a current-comparison reading mode for a differential storage cell without increasing a storage array area, further enlarging a read window to realize more stable data reading based on a more stable differential reading principle relative to a traditional reference current type.

To solve the above technical problem, the present application provides a differential memory comprising m+1 rows of storage cells, each row comprises n array blocks, each array block comprises j array cells, each array cell comprises M+1 storage cells, bit lines of M+1 storage cells of an (x)th array cell and bit lines of M+1 storage cells of an (x−1)th array cell are arranged sequentially in a staggered and spaced pattern in a physical arrangement, m is an integer greater than or equal to 0, M is a positive integer, j is an even number greater than 1, n is a positive integer, x is an even number less than or equal to j, bit lines of storage cells of an identical array cell share an identical column address, and a 0th storage cell and a 1st storage cell in M+1 storage cells of each array cell store inverted data.

In some embodiments, the 0th storage cell and the 1st storage cell storing inverted data in the M+1 storage cells of each array cell, as a pair of differential storage cells, can be located at any position in the array cell.

In some embodiments, M is 1, 2, 3, 4, 5, 9 or 17.

In some embodiments, j is 2, 4, 6, 8, 16 or 32.

In some embodiments, the differential memory further comprises n groups of sensitive amplifiers;
each group of sensitive amplifiers comprises M storage-cell sensitive amplifiers;
a 1st sensitive amplifier of a (y)th group of sensitive amplifiers is used to read stored data in a 0th storage cell of a selected array cell of a (y)th array block, y being a positive integer less than or equal to n;
a positive input of the 1st sensitive amplifier of the (y)th sensitive amplifier is connected to a reading current c1<0> of the 0th storage cell in the selected array cell of the (y)th array block; and a negative input is connected to a reading current clb<0> of the 1st storage cell in the selected array cell of the (y)th array block;
a (k)th sensitive amplifier of the (y)th group of sensitive amplifiers is used to read stored data of a (k)th storage cell in the selected array cell of the (y)th array block, k being an integer less than or equal to M and greater than 1; and
a positive input of the (k)th sensitive amplifier of the (y)th group of sensitive amplifiers is connected to a reading current c1<k−1> of the (k)th storage cell in the selected array cell of the (y)th array block; and a negative input is connected to an average value of the reading current c1<0> of the 0th storage cell in the selected array cell of the (y)th array block and the reading current c1b<0> of the 1st storage cell in the selected array cell of the (y)th array block.

In some embodiments, the differential memory comprises a group of sensitive amplifiers;
the group of sensitive amplifiers comprises M storage-cell sensitive amplifiers;
a positive input of a 1st sensitive amplifier of the group of sensitive amplifiers is each connected to a reading current c1<0> of a 0th storage cell of each array cell by different gated transistors, and a negative input is each connected to a reading current c1b<0> of a 1st storage cell of each array cell by different gated transistors; and
a positive input of a (k)th sensitive amplifier of the group of sensitive amplifiers is each connected to a reading current c1<k−1> of a (k)th storage cell of each array cell by different gated transistors; and k is an integer less than or equal to M and greater than 1, and a negative input is each connected to the reading current c1<0> of the 0th storage cell of each array cell and to the reading current c1b<0> of the 1st storage cell by different gated transistors.

In some embodiments, the memory is a sonos or EEPROM memory.

In some embodiments, an output of the sensitive amplifier is connected to a readout circuit.

In some embodiments, the differential memory further comprises a column address decoder; and
the column address decoder is used for decoding according to an i-bit input address to output j bit line addresses Y₀˜Yⱼ₋₁, j=2ⁱ, i being a positive integer.

In the differential memory of the present application, the bit lines of the M+1 storage cells of the (x)th array cell and the bit lines of the M+1 storage cells of the (x−1)th array cell are arranged sequentially in a staggered and spaced pattern in a physical arrangement, and thus, bit lines of a group of storage cell arrays storing M bits of data with M+1 storage cells are separated by bit lines of another group of storage cell arrays, and a misreading risk resulted from crosstalk caused by simultaneous discharging of two adjacent bit lines during reading can be avoided while retaining a current-comparison reading mode for a differential storage cell without increasing a storage array area, further enlarging a read window to realize more stable data reading based on a more stable differential reading principle relative to a traditional reference current type.

### BRIEF DESCRIPTION OF THE DRAWINGS

To clarify the technical solution of the present application, the figures to be used in the application are briefly introduced below. Obviously, the figures in the description below are only some embodiments of the present application, and according to these figures, other figures can be obtained by those of ordinary skill in the art without the exercise of inventive effort.

FIG. 1 shows an existing reference-current-type reading mode in which a current of a storage cell is compared with a reference current, and a storage array arrangement;

FIG. 2 shows a reading mode for an existing differential comparison storage array, and a storage array arrangement;

FIG. 3a is a schematic diagram of a circuit structure of a sensitive amplifier realizing signal superposition for c1<0> and c1b<0>;

FIG. 3b is an improved reading mode for a differential contrast storage array with M+1-bit storage cells storing M bits of data (M=3), and a storage cell array arrangement;

FIG. 4a is a schematic diagram of discharging on a differential address bit line of a differential array cells during reading;

FIG. 4b is a schematic diagram of discharging of a differential address bit line of a differential array cell after crosstalk avoidance;

FIG. 5a shows a differential contrast storage array with 4 sonos storage cells storing 3-bit and without shielded line isolation in the middle;

FIG. 5b shows a differential contrast storage array with 4 sonos storage cells storing 3-bit and with shielded line isolation in the middle;

FIG. 6 shows a schematic diagram of read window reduction of the differential contrast storage array without shield line isolation in the middle shown in FIG. 5a;

FIG. 7 is a schematic diagram of a structure of an embodiment of a differential memory of the present application;

FIG. 8 is a schematic diagram of a spaced address arrangement array and selected circuit reading with M=3 of a structure of an embodiment of a differential memory of the present application.

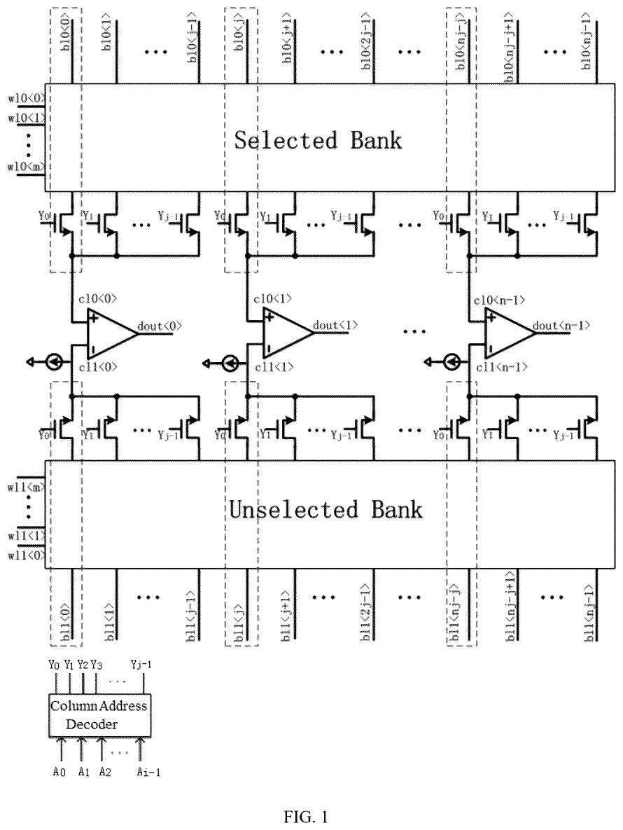

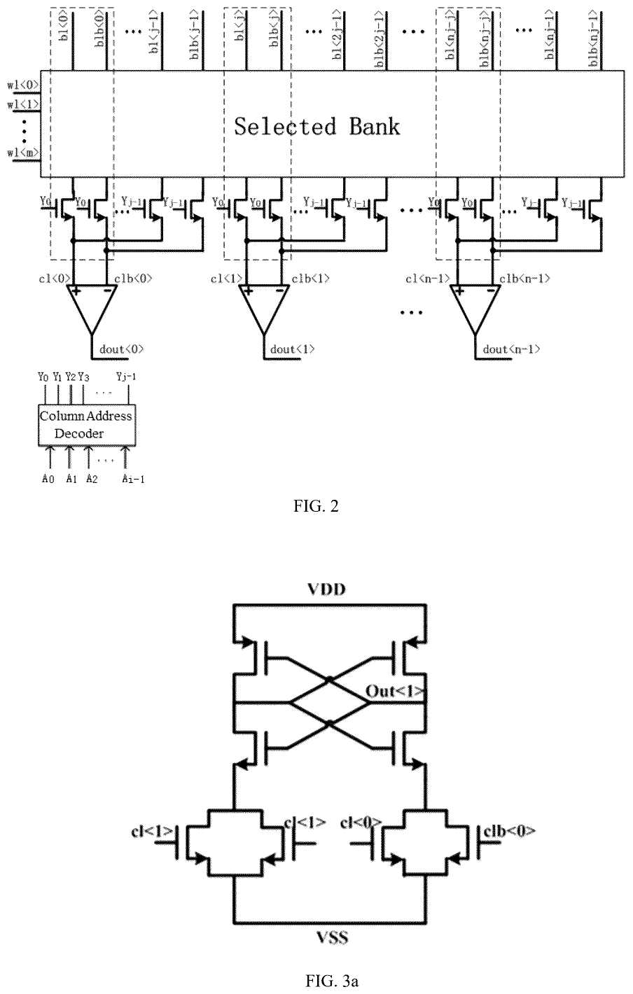

### DETAILED DESCRIPTION OF THE DISCLOSURE

The technical solution in the embodiment of the present application is described clearly and completely below in conjunction with the figures in the embodiment of the present application. Obviously, the described embodiments are a part of the embodiments of the present application, not all the embodiments. Based on the embodiments in the present application, all other embodiments obtained by those of ordinary skill in the art without the exercise of inventive effort fall within the scope of protection of the present application.

Words “first”, “second”, or the like used in this application do not indicate any order, number or importance, but are only used to distinguish different components. Words “including”, “comprising”, or the like mean that the element or article preceded by the words covers the element or article and equivalents thereof listed after the words, but does not exclude other components or articles. Words “connected”, “attached”, or the like are not limited to physical or mechanical connections, but may include electrical connections, either direct or indirect. “Upper”, “lower”, “left”, “right”, “front”, “back”, etc. are only used to indicate relative positional relationships, and after absolute positions of described objects change, the relative positional relationships may also change accordingly.

It should be noted that the embodiments in the present application and the features in the embodiments may be combined without contradictory.

### Embodiment I

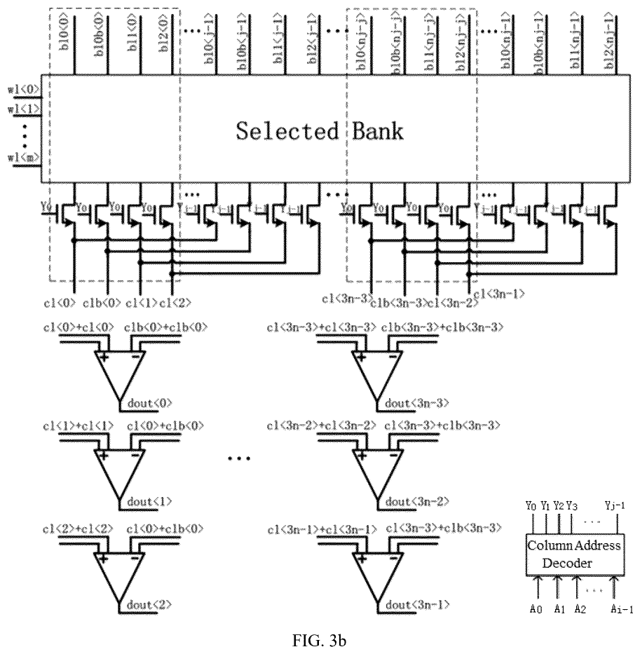

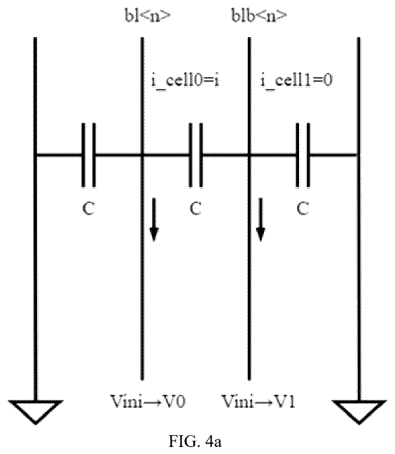

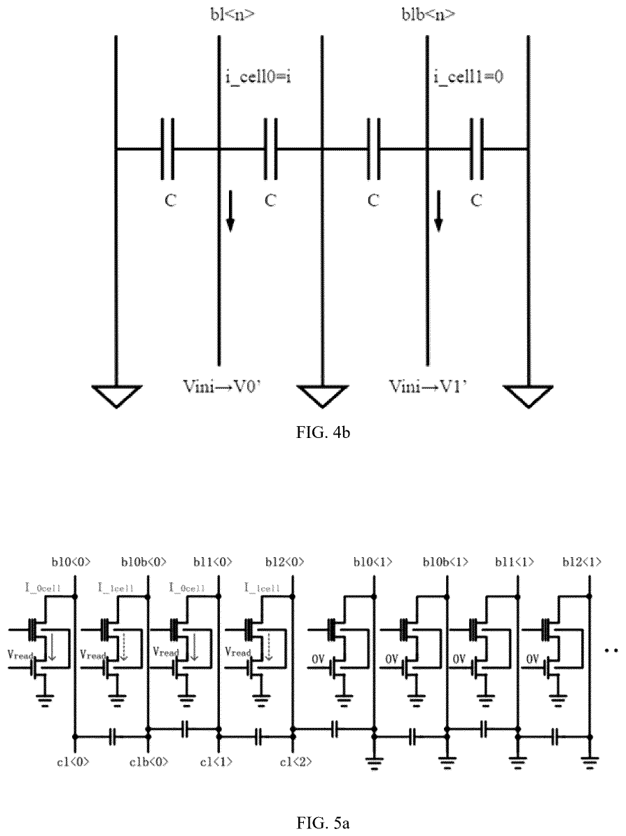

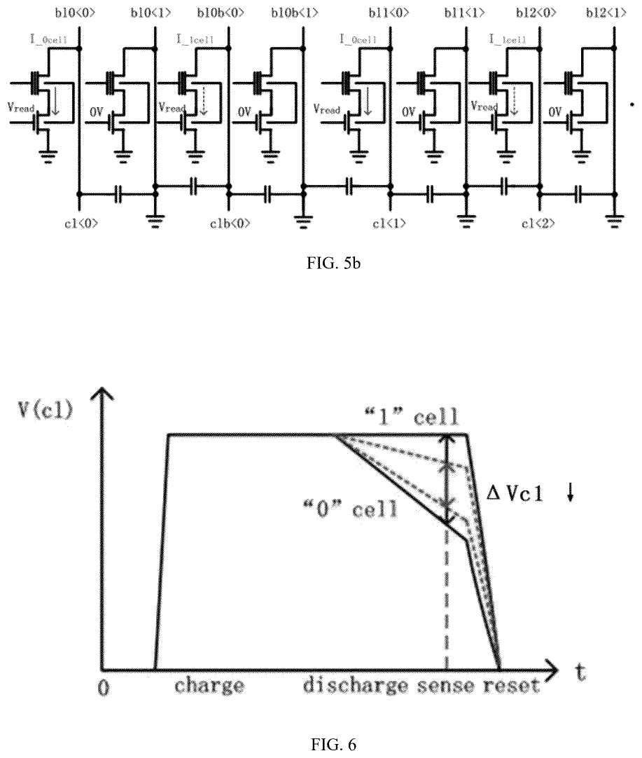

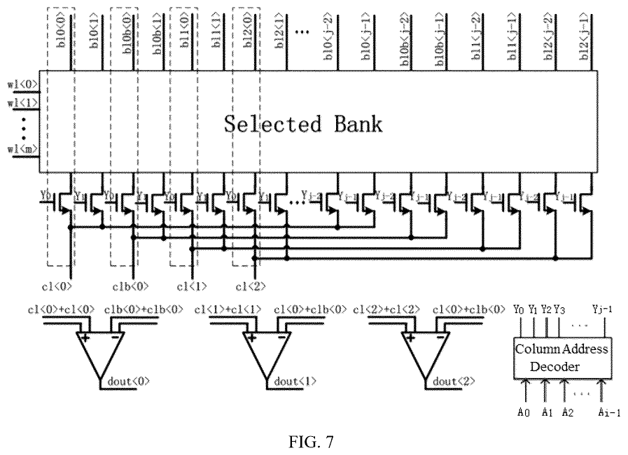

Referring to FIGS. 3b and 7, a differential memory comprises m+1 rows of storage cells, each row comprises n array blocks, each array block comprises j array cells, each array cell comprises M+1 storage cells, bit lines of M+1 storage cells of an (x)th array cell and bit lines of M+1 storage cells of an (x−1)th array cell are arranged sequentially in a staggered and spaced pattern in a physical arrangement, m is an integer greater than or equal to 0, M is a positive integer, j is an even number greater than 1, n is a positive integer, x is an even number less than or equal to j, bit lines of storage cells of an identical array cell share an identical column address, and a 0th storage cell and a 1st storage cell in M+1 storage cells of each array cell store inverted data.

Preferably, the 0th storage cell and the 1st storage cell storing inverted data in the M+1 storage cells of each array cell, as a pair of differential storage cells, may be located at any position in the array cell.

Preferably, M is 1, 2, 3, 4, 5, 9, 17 or the like.

Preferably, j is 2, 4, 6, 8, 16, 32 or the like.

Preferably, the memory may be a sonos or EEPROM memory, etc., and any memory that can read data by detecting a change in a voltage or a current of a bit line is an application object of the present application.

In the differential memory of embodiment 1, the bit lines of the M+1 storage cells of the (x)th array cell and the bit lines of the M+1 storage cells of the (x−1)th array cell are arranged sequentially in a staggered and spaced pattern in a physical arrangement, and thus, bit lines of a group of storage cell arrays storing M bits of data with M+1 storage cells are separated by bit lines of another group of storage cell arrays, and a misreading risk resulted from crosstalk caused by simultaneous discharging of two adjacent bit lines during reading can be avoided while retaining a current-comparison reading mode for a differential storage cell without increasing a storage array area, further enlarging a read window to realize more stable data reading based on a more stable differential reading principle relative to a traditional reference current type.

Taking M=3 as an example, referring to FIG. 7, bit lines (bl0<0>, bl0b<0>, bl1<0>, and bl2<0>) of 4 storage cells of a 0th array cell of an identical array block of an identical row share an identical bit line address <0>, bit lines (bl0<1>, bl0b<1>, bl1<1>, and bl2<1>) of 4 storage cells of a 1st array cell of an identical array block of an identical row share an identical bit line address <1>, bit lines (bl0<j−2>, bl0b<j−2>, bl1<j−2>, and bl2<j−2>) of 4 storage cells of a (j−2)th array cell of an identical array block of an identical row share an identical bit line address <j−2>, and bit lines (bl0<j−1>, bl0b<j −1>, bl1<j−1>, and bl2<j−1>) of 4 storage cells of a (j−1)th array cell of an identical array block of an identical row share an identical bit line address <j−1>; the bit lines (bl0<0>, bl0b<0>, bl1<0>, and bl2<0>) of the 4 storage cells of the 0th array cell of an identical array block of an identical row and the bit lines (bl0<1>, bl0b<1>, bl1<1>, bl2<1>) of the 4 storage cells of the 1st array cell are arranged sequentially in a staggered and spaced pattern in a physical arrangement (i.e., bl0<0>, bl0<1>, bl0b<0>, bl0b<1>, bl1<0>, bl1<1>, bl2<0>, and bl2<0>); and the bit lines (bl0<j−2>, bl0b<j−2>, bl1<j−2>, and bl2<j−2>) of the 4 storage cells of the (j−2)th array cell of an identical array block of an identical row and the bit lines (bl0<j−1>, bl0b<j−1>, bl1<j−1>, and bl2<j−1>) of the 4 storage cells of the (j−1)th array cell are arranged sequentially in a staggered and spaced pattern in a physical arrangement (i.e., bl0<j−2>, bl0<j−1>, bl0b<j−2>, bl0b<j−1>, bl1<j−2>, bl1<j−1>, bl2<j−2>, and bl2<j−1>);
when the bit line address <0> is selected for reading in a read cycle, the 4 storage cells of the 0th array cell to which the bit lines (bl0<0>, bl0b<0>, bl1<0>, and bl2<0>) are connected are discharged simultaneously after being pre-charged, current-comparison reading is performed for the storage cells of the 0th array cell, and at this point, since the bit line address <1> between every two bit lines of the 4 storage cells of the 0th array cell is not selected, potentials of the bit lines (bl0<1>, bl0b<1>, bl1<1>, and bl2<1>) of the 4 storage cells of the 1st array cell in the identical row is constant at 0 during this period, and the bit lines can be used as shielded lines to avoid crosstalk occurring between the bit lines, at either side of the bit lines, (bl0<0>, bl0b<0>, bl1<0>, and bl2<0>) of the 4 storage cells of the 0th array cell that are being discharged, so that the read window is not affected, and is further enlarged based on an original array arrangement.

### Embodiment II

Based on embodiment I, the differential memory further comprises n groups of sensitive amplifiers;
each group of sensitive amplifiers comprises M storage-cell sensitive amplifiers;
a 1st sensitive amplifier of a (y)th group of sensitive amplifiers is used to read stored data in a 0th storage cell of a selected array cell of a (y)th array block, y being a positive integer less than or equal to n;
a positive input of the 1st sensitive amplifier of the (y)th group of sensitive amplifier is connected to a reading current c1<0> of the 0th storage cell in the selected array cell of the (y)th array block; and a negative input is connected to a reading current c1b<0> of the 1st storage cell in the selected array cell of the (y)th array block;
a (k)th sensitive amplifier of the (y)th group of sensitive amplifiers is used to read stored data of a (k)th storage cell in the selected array cell of the (y)th array block, k being an integer less than or equal to M and greater than 1; and
a positive input of the (k)th sensitive amplifier of the (y)th group of sensitive amplifiers is connected to a reading current c1<k−1> of the (k)th storage cell in the selected array cell of the (y)th array block; and a negative input is connected to an average value of the reading current c1<0> of the 0th storage cell in the selected array cell of the (y)th array block and the reading current c1b<0> of the 1st storage cell in the selected array cell of the (y)th array block.

Preferably, an output of the sensitive amplifier is connected to a readout circuit.

Several transmission gate circuits, combinational logic circuits, timing logic circuits, and driver circuits may be provided for a selected storage cell, to connect the storage cell to the sensitive amplifier, and connect the sensitive amplifier to the readout circuit; and timing of gating, amplifying, and reading is controlled.

In the differential memory of embodiment 2, n groups of sensitive amplifiers are provided to correspondingly read stored data of n array blocks; 1 bit of stored data is read from the 0th storage cell and the 1st storage cell, storing inverted data, of the (x)th array cell by a differential-reading mode; and with remained M−1 storage cells, reading is performed by comparing the reading currents of the remaining storage cells of the (x)th array cell with the average value of the reading currents of the 0th storage cell and the 1st storage cell, storing inverted data, of the (x)th array cell, so as to obtain a result above or below the average value, which is defined as reading 1 or 0.

### Embodiment III

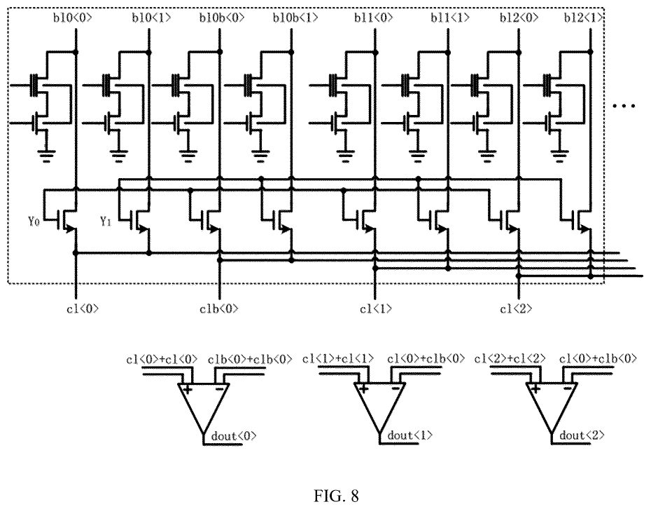

Based on embodiment I, referring to FIGS. 7 and 8, the differential memory comprises a group of sensitive amplifiers;
the group of sensitive amplifiers comprises M storage-cell sensitive amplifiers;
a positive input of a 1st sensitive amplifier of the group of sensitive amplifiers is each connected to a reading current c1<0> of a 0th storage cell of each array cell by different gated transistors, and a negative input is each connected to a reading current c1b<0> of a 1st storage cell of each array cell by different gated transistors; and
a positive input of a (k)th sensitive amplifier of the group of sensitive amplifiers is each connected to a reading current c1<k−1> of a (k)th storage cell of each array cell by different gated transistors; and k is an integer less than or equal to M and greater than 1, and a negative input is each connected to the reading current c1<0> of the 0th storage cell of each array cell and to the reading current c1b<0> of the 1st storage cell by different gated transistors.

Preferably, an output of the sensitive amplifier is connected to a readout circuit.

Several transmission gate circuits, combinational logic circuits, timing logic circuits, and driver circuits may be provided for a gated storage cell, to connect the storage cell to the sensitive amplifier, and connect the sensitive amplifier to the readout circuit; and timing of gating, amplifying, and reading is controlled.

### Embodiment IV

Based on the differential memory in embodiment II, the differential memory further comprises a column address decoder; and
the column address decoder is used for decoding according to an i-bit input address to output j bit line addresses Y₀˜Yⱼ₋₁, j=2ⁱ, i being a positive integer.

Referring to FIG. 7, taking reading of three bits of data, with M=3, as an example, an i-bits (A0, A1, . . . , Ai−1) column address decoder outputs j different column addresses Y0, Y1, . . . , Yj−1 which are connected to 4 bit lines (bl0, bl0b, bl1, bl2) of different array cells of a selected array block, respectively. With 3 bits of data read from a 4-bit storage cell, it requires that a pair of storage cells is differential, i.e., a storage cell on the bit line bl0b stores inverted data relative to the date in a storage cell on the bit line bl0, a gated transistor of a column address is turned on during read to input a reading current cl (cl0, cl0b, bl1, bl2) of a storage cell on a bit line (bl0, cl0b, cl1, cl2) into three sensitive amplifiers, currents of a pair of differential storage cells are compared, and currents of other storage cells are compared with an average current of the differential storage cells to read 3 bits of data. Referring to FIG. 8, 4 bit lines bl0<0>, bl0b<0>, bl1<0>, and bl2<0> of an identical column address and 4 bit lines bl0<1>, bl0b<1>, bl1<1>, and bl2<1> controlled by another column address are arranged in a staggered pattern in physical positions to realize address spacing arrangement, bit lines of j column address are thus spaced in a staggered pattern in pairs to obtain a full array, and referring to FIG. 7, the column address Y0 is subjected to reading by selecting a bit line in alternate columns. When an address <0> is read, bl0<0>, bl0b<0>, bl1<0>, and bl2<0> are precharged to an identical potential and then discharged through the storage cell on each bit line; and since bit lines of addresses <1> are not selected, bl0<1>, bl0b<1>, bl1<1>, and bl2<1> are grounded under a read action as shield lines for the bit lines of the addresses <0>, to avoid mutual crosstalk when the bit lines of the addresses <0> are discharged.

When the number of output bits exceeds M, the array block as in the figure is repeated. When the number of read bits is not an integer multiple of M, storage array cells with different M values can be mixed for flexible handling.

Only preferred embodiments of the present application are described above and are not intended to limit the present application. Any modifications, equivalent replacements, improvements, etc. made within the spirit and principle of the present application shall be included within the scope of protection of the present application.

What is claimed is:

1. A differential memory, wherein the differential memory comprises m+1 rows of storage cells, each row comprises n array blocks, each array block comprises j array cells, each array cell comprises M+1 storage cells, bit lines of M+1 storage cells of an (x)th array cell and bit lines of M+1 storage cells of an (x−1)th array cell are arranged sequentially in a staggered and spaced pattern in a physical arrangement, m is an integer greater than or equal to 0, M is a positive integer, j is an even number greater than 1, n is a positive integer, x is an even number less than or equal to j, bit lines of storage cells of an identical array cell share an identical column address, and a 0th storage cell and a 1st storage cell in M+1 storage cells of each array cell store inverted data.

2. The differential memory according to claim 1, wherein
the 0th storage cell and the 1st storage cell storing inverted data in the M+1 storage cells of each array cell, as a pair of differential storage cells, is capable of being located at any position in the array cell.

3. The differential memory according to claim 1, wherein
M is 1, 2, 3, 4, 5, 9 or 17.

4. The differential memory according to claim 1, wherein
j is 2, 4, 6, 8, 16 or 32.

5. The differential memory according to claim 1, wherein
the differential memory further comprises n groups of sensitive amplifiers;
each group of sensitive amplifiers comprises M storage-cell sensitive amplifiers;
a 1st sensitive amplifier of a (y)th group of sensitive amplifiers is used to read stored data in a 0th storage cell of a selected array cell of a (y)th array block, y being a positive integer less than or equal to n;
a positive input of the 1st sensitive amplifier of the (y)th sensitive amplifier is connected to a reading current c1<0> of the 0th storage cell in the selected array cell of the (y)th array block; and a negative input is connected to a reading current c1b<0> of the 1st storage cell in the selected array cell of the (y)th array block;
a (k)th sensitive amplifier of the (y)th group of sensitive amplifiers is used to read stored data of a (k)th storage cell in the selected array cell of the (y)th array block, k being an integer less than or equal to M and greater than 1; and
a positive input of the (k)th sensitive amplifier of the (y)th group of sensitive amplifiers is connected to a reading current c1<k−1> of the (k)th storage cell in the selected array cell of the (y)th array block; and a negative input is connected to an average value of the reading current c1<0> of the 0th storage cell in the selected array cell of the (y)th array block and the reading current c1b<0> of the 1st storage cell in the selected array cell of the (y)th array block.

6. The differential memory according to claim 1, wherein
the differential memory comprises a group of sensitive amplifiers;
the group of sensitive amplifiers comprises M storage-cell sensitive amplifiers;
a positive input of a 1st sensitive amplifier of the group of sensitive amplifiers is each connected to a reading current c1<0> of a 0th storage cell of each array cell by different gated transistors, and a negative input is each connected to a reading current c1b<0> of a 1st storage cell of each array cell by different gated transistors; and
a positive input of a (k)th sensitive amplifier of the group of sensitive amplifiers is each connected to a reading current c1<k−1> of a (k)th storage cell of each array cell by different gated transistors; and k is an integer less than or equal to M and greater than 1, and a negative input is each connected to the reading current c1<0> of the 0th storage cell of each array cell and to the reading current c1b<0> of the 1st storage cell by different gated transistors.

7. The differential memory according to claim 1, wherein
the memory is a sonos or EEPROM memory.

8. The differential memory according to claim 5, wherein
an output of the sensitive amplifier is connected to a readout circuit.

9. The differential memory according to claim 1, wherein
the differential memory further comprises a column address decoder; and
the column address decoder is used for decoding according to an i-bit input address to output
j bit line addresses Y₀˜Yⱼ₋₁, j=2ⁱ, i being a positive integer.
